(19) United States
(12) Patent Application Publication
(10) Pub. No.: US 2009/0322389 A1
(43) Pub. Date: Dec. 31, 2009

(54) JITTER ATTENUATING DELAY LOCKED LOOP (DLL) USING A REGENERATIVE DELAY LINE

(76) Inventors: Guneet Singh, Santa Clara, CA (US); Roan M. Nicholson, San Jose, CA (US); Frank O'Mahony, Portland, OR (US); Sitaraman V. Iyer, Santa Clara, CA (US)

Correspondence Address: RYDER IP LAW;C/O CPA Global, P. O. BOX 52050, MINNEAPOLIS, MN, 55402, US

(21) Appl. No.: 12/145,779

(22) Filed: Jun. 25, 2008

(51) Int. Cl. H03L 7/06; H03H 11/26

(52) U.S. Cl. 327/158; 327/261

(57) ABSTRACT

In general, in one aspect, the disclosure describes a delay locked loop (DLL) with a regenerative delay line that includes a cascade of delay stages. A first delay stage includes a two-input delay device which receives a 180 degree phase shifted signal as feedback. This feedback signal configures the delay line into a regenerative amplifier, the frequency response of which has peaking or resonance at the input frequency which results in jitter filtering. The amount of regeneration is determined by relative strength of an input signal and the feedback signal. Relative strength is determined by relative size of devices receiving the signals. The resonant frequency (with or without oscillations) of the delay line may automatically be tuned to the incoming clock frequency by the DLL control loop. Each of the other delay stages may include two-input delay devices with the inputs shorted for uniformity.

### BACKGROUND

Delay Locked Loops (DLLs) can be used to generate equally spaced multiple clock phases. The phase shifts in a DLL are generated using a delay line that includes a cascade of delay stages or elements where each stage delays the phase a defined amount (e.g., 22.5 degrees, 45 degrees, 90 degrees). The delay provided by each stage is created by an active voltage, current, or digitally control delay element. Most commonly used delay elements have higher amplitude gain at DC compared to its gain at the operating clock frequency. This difference between DC gain and operating frequency gain (or amplitude gain roll-off) amplifies jitter and duty cycle error. Larger delay per delay stage implies higher amplitude gain roll-off and hence higher jitter amplification. Since the delay stages in a delay line are cascaded, the aggregate amplitude gain roll-off of the whole delay line is much higher compared to a single delay element, which results in even more jitter amplification through the delay line.

Reducing the delay provided by each delay element in the delay line reduces the amplitude roll-off of each delay element and the resulting jitter amplification. However, reducing the amount of delay provided by each delay element requires additional delay elements (stages). Increasing the total number of stages required to generate a 180 degree phase shift (which effectively means reducing the amount of delay per stage) increases the power consumption of the DLL. Accordingly, there is a trade-off between jitter amplification and power consumption in the design of DLLs.

Regardless of the number of stages, the lowest jitter amplification that can be achieved with conventional DLLs is 1 (e.g., output jitter is at least equal to the input jitter). Conventional DLLs cannot attenuate incoming jitter on the input clock.

### BRIEF DESCRIPTION OF THE DRAWINGS

The features and advantages of the various embodiments will become apparent from the following detailed description in which:

FIG. 1 illustrates an example delay locked loop (DLL);

FIG. 2 illustrates an example delay line;

FIG. 3 illustrates an example regenerative delay line, according to one embodiment;

FIG. 4 illustrates an example dual input voltage controlled delay element utilized in the example regenerative delay line of FIG. 3, according to one embodiment;

FIG. 5 illustrates an example jitter transfer function model for the example regenerative delay line of FIG. 3, according to one embodiment;

FIG. 6 graphically illustrates an example jitter transfer function for the example regenerative delay line of FIG. 3, according to one embodiment; and

FIG. 7 illustrates an example graph comparing traditional DLLs to regenerative DLLs, according to one embodiment.

### DETAILED DESCRIPTION

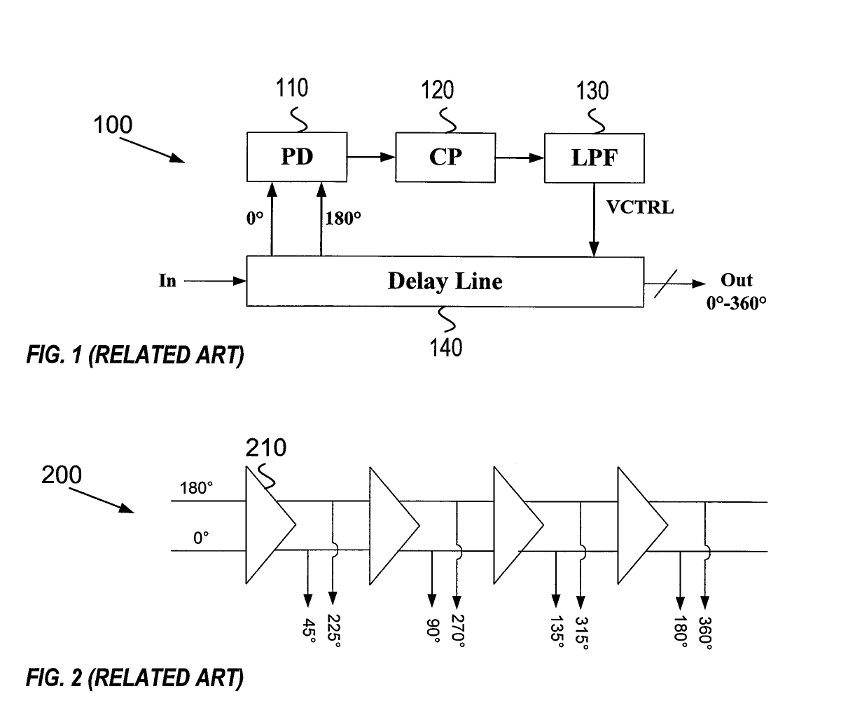

FIG. 1 illustrates an example delay locked loop (DLL) 100. The DLL 100 may include a phase detector (PD) 110, a charge pump (CP) 120, a low pass filter (LPF) 130 and a delay line 140. The delay line 140 may receive an incoming clock (In) and may generate multiple equi-spaced clock phases from 0°-360° (0 to 2π). Certain clock phases (0°, 180°) may be sent as inputs to the PD 110 to measure the delay of the line. The PD 110 may generate an UP/DOWN signal by comparing the phases from the delay line 140. The CP 120 and LPF 130 may generate a filtered control voltage signal (VCTRL) for the delay line 140. The clock phases generated by the delay line 140 may be subsequently used for fine phase adjustment (e.g., by a Phase Interpolator) further down stream.

FIG. 2 illustrates an example delay line 200 (e.g., 140 of FIG. 1). The delay line 200 may include a plurality of delay stages. Each delay stage may include a delay device (e.g., voltage controlled delay element) 210. Each delay device 210 may provide a phase shift (e.g., 45 degrees). The delay device 210 can be approximated as a single pole system. In a single pole system, a 45 degree phase shift results in an amplitude gain roll-off of 3 dB, assuming small signal behavior. As such, each stage of the delay line 200, providing 45 degree phase shift, has an amplitude gain roll-off of approximately 3 dB at the operating frequency of the DLL compared to the DC gain. A 3 dB difference between DC Gain and operating frequency implies that duty cycle error caused by a DC input common-mode offset in the signal is amplified 3 dB more than the signal, resulting in duty cycle error amplification. Jitter (especially high frequency jitter) like duty cycle error is also amplified. As the delay line 200 includes multiple stages (e.g., 4), jitter is amplified in each stage (with successive stages amplifying the previously amplified jitter).

Reducing the phase shift (e.g., from 45° to 30° or a lower number) of each delay element reduces the amplitude roll-off at the clock frequency and associated jitter amplification. However, reducing the phase shift may result in additional delay elements being used to generate the 0°-360° clocks (e.g., from 4 to 6). Increasing the number delay elements (which effectively means reducing the amount of delay per stage) may increase the power of the DLL. Accordingly, there may be a tradeoff between jitter amplification and power consumption. Furthermore, the outgoing jitter will at least equal the incoming jitter (jitter amplification factor will be at least 1) as the delay lines 200 do not attenuate incoming jitter on the input clock.

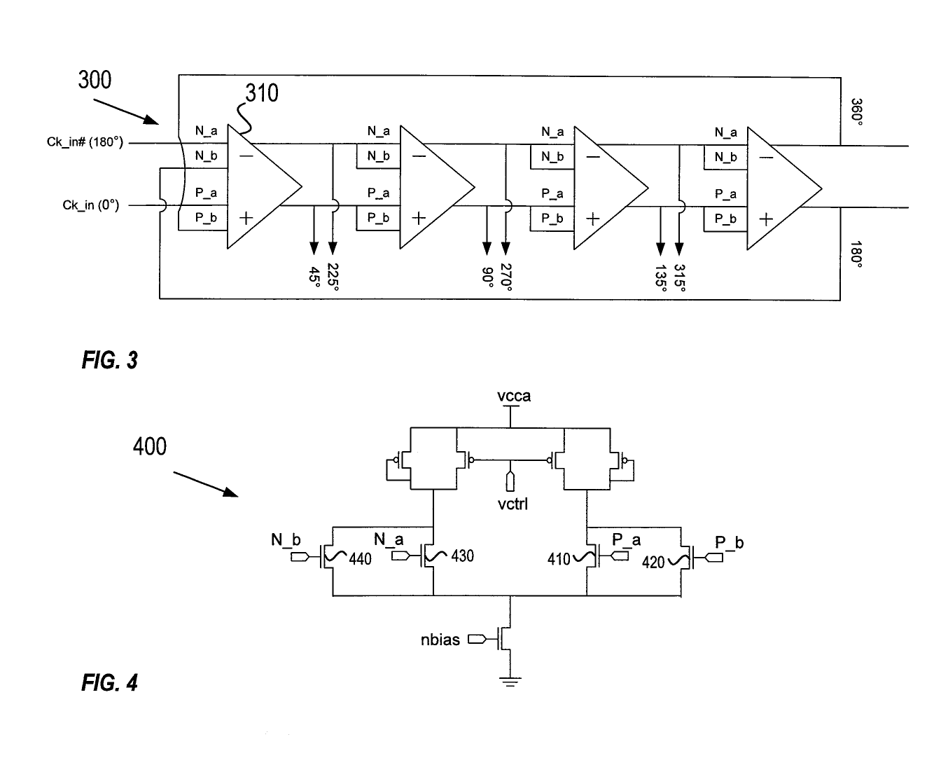

FIG. 3 illustrates an example delay line 300 utilizing regeneration (positive feedback). The delay line 300 includes delay devices 310 (e.g., active) to provide the phase shift in stages. For example, the delay line 300 may include four stages where each stage provides a phase shift of 45 degrees. The delay elements 310 may include two positive inputs (P_a, P_b) and two negative inputs (N_a, N_b). The delay devices 310 may be delay elements or delay cells that are controlled by various means including but not limited to voltage, current or capacitance or may be digitally controlled. It should be noted that the delay line 300 is illustrated as having positive and negative inputs in order to receive differential signals but is in no way intended to be limited thereto.

FIG. 4 illustrates an example dual input voltage controlled delay element 400 (e.g., 310 of FIG. 3). The delay element 400 may include two devices (e.g., transistors) 410, 420 receiving the positive inputs (P_a, P_b) and two devices (e.g., transistors) 430, 440 receiving the negative inputs (N_a, N_b). The devices 410, 420, 430, 440 are illustrated as transistors but are in way intended to be limited thereto. For example, the devices 410, 420, 430, 440 may be invertors without departing from the current scope.

The first delay element 310 may receive at a first pair of inputs (P_a, N_a) the incoming clock signal (ck_in, ck_in#) and may receive at it's a second pair of inputs (P_b, N_b) feedback from end of the delay line (after a 180 degree phase shift). The positive output (180 degrees) of the delay line 300 (last delay element 310) may be provided to a negative input (N-b) of the first delay element 310 and the negative output (360 degrees) of the delay line 300 may be provided to a positive input (P-b) of the first delay element 310.

The two positive and two negative inputs may be shorted together for each of the other delay elements 310. The outputs of the first delay element 310 may be provided as inputs to the second delay element 310 and so on. The positive output of a proceeding delay element 310 may be provided to both positive inputs of succeeding delay element 310 and the negative output of a proceeding delay element 310 may be provided to both negative inputs of succeeding delay element 310. Using the same delay element 310 for each phase shift and shorting the inputs may provide uniformity in the design of the delay elements and reduces variability in operation that may be caused by utilizing different designed delay elements (e.g., using single input delay element for all delay elements except first delay element).

The feedback in the delay line 300 configures the delay line 300 into a regenerative amplifier, the frequency response of which has peaking or resonance at the input frequency when the loop is delay locked. Peaking/resonance at the input frequency results in jitter filtering. The amount of regeneration (or positive feedback) is determined by relative size of devices 410, 430 (a inputs) to the devices 420, 440 (b inputs). The devices 410, 420 may control the strength of the ck_in (0°) with respect to the feedback (360°) and the devices 430, 440 may control the strength of the ck_in# (180°) with respect to the feedback (180°).

The ratio of strength of the “a” inputs (clock signals) to the “b” inputs (feedback signals) controls the amount of regeneration. The strength of the feedback signal may be considered β and the strength of the input signal may be considered 1−β. The larger the value of β the stronger the feedback signal is. Increasing β implies increased regeneration and increased jitter filtering. Increasing β past a certain level (e.g., above 0.5) may configure the delay line 300 into an injection locked oscillator that is tuned by the DLL loop. For β<1, resonant frequency (with or without oscillations) of the delay line 300 may automatically be tuned to the incoming clock frequency by the DLL control loop and jitter filtering may be achieved.

Jitter filtering may be achieved with or without oscillations in the delay line 300. The delay line 300 may work over a wide range of frequencies (e.g., 2 GHz-5.5 GHz) limited only by the lock range of the DLL. The feedback/regeneration may need to be shut-off during startup and lock of a regenerative DLL and enabled only after the DLL has locked.

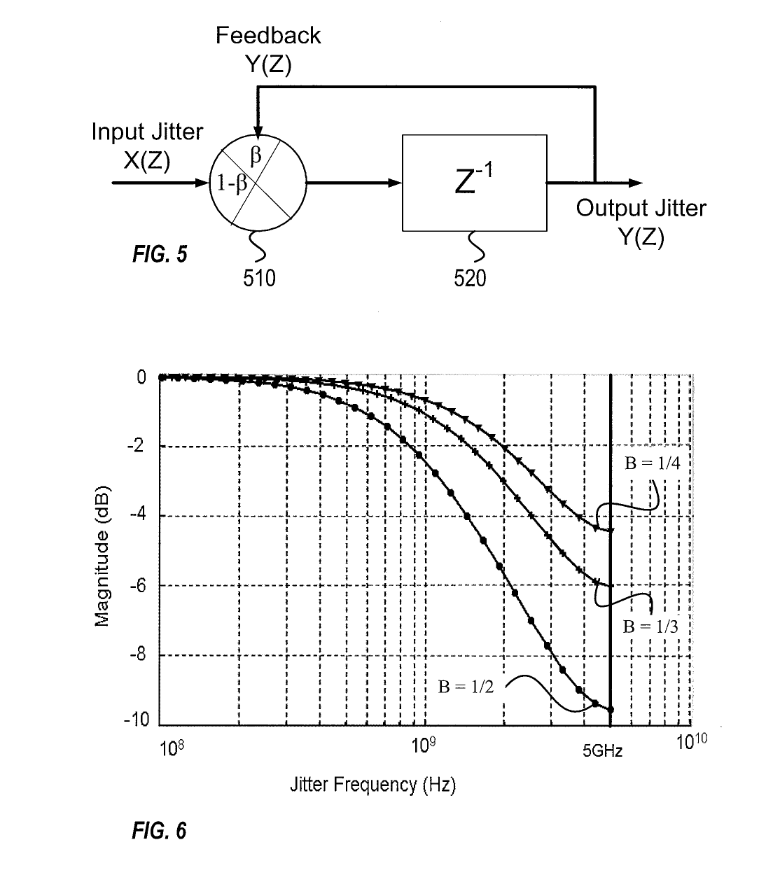

FIG. 5 illustrates an example jitter transfer function model for the regenerative delay line 300 of FIG. 3. An adder 510 represents the input jitter X(Z) and the output jitter/feedback Y(Z) being inputs to a delay line, and Z⁻¹ 520 represents a 180 degree phase shift through the delay line. The jitter transfer function H(Z) of the regenerative delay line is a low pass function representing attenuation of the input jitter, where H(Z)=(1−β)/(1−β*Z⁻¹).

FIG. 6 graphically illustrates an example jitter transfer function for the regenerative delay line 300 of FIG. 3. As β increases the amount of jitter attenuation increases. For example at a frequency of 5 GHz, β=¼ results in approximately 4.5 dB high-frequency jitter attenuation, β=⅓ results in approximately 6 dB high-frequency jitter attenuation, and β=½ results in approximately 9.5 dB high-frequency jitter attenuation.

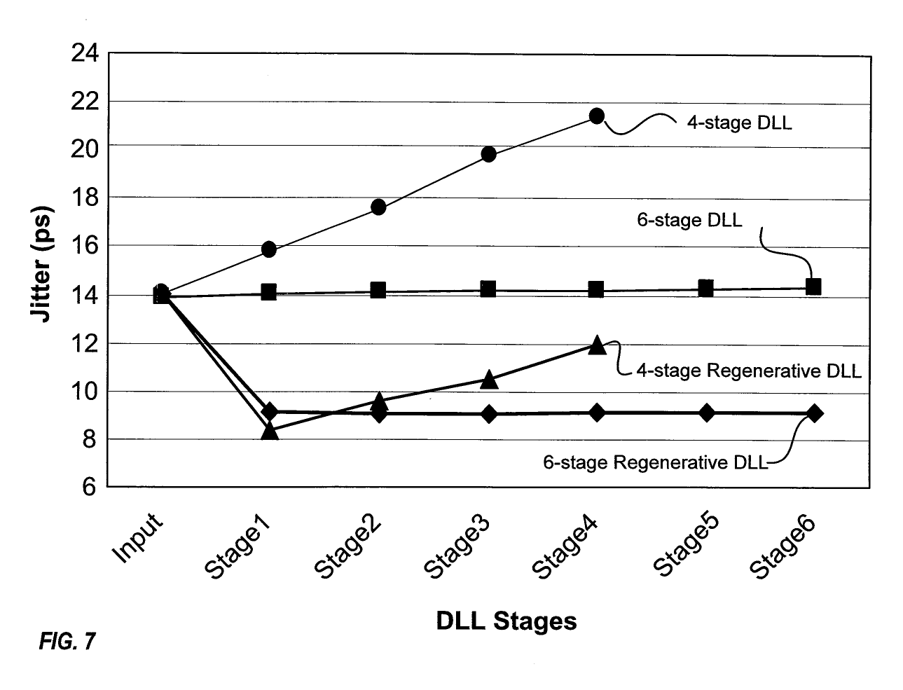

FIG. 7 illustrates an example graph comparing traditional DLLs to regenerative DLLs. The graph assumes that an input jitter impulse of 14 ps is received. For a traditional 4-stage DLL the jitter gets amplified to approximately 21 ps implying 50% amplification in jitter (jitter amplification factor=1.5). For a regenerative 4 stage DLL the jitter is attenuated to approximately 12 ps achieving 15% jitter attenuation (jitter amplification factor=0.85). For a traditional 6-stage DLL the jitter gets amplified to approximately 14.5 ps implying 4% jitter amplification (jitter amplification factor=1.04). For a regenerative 6-stage the jitter is attenuated to approximately 9 ps achieving jitter attenuation of 35% (jitter amplification factor=0.65).

Although the disclosure has been illustrated by reference to specific embodiments, it will be apparent that the disclosure is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

1. A delay line comprising
a plurality of delay stages, wherein each delay stage delays the phase of an input signal a defined amount, wherein each delay stage includes a first input, a second input, and an output, wherein a first delay stage receives the input signal at the first input and the output of a last delay stage as feedback at the second input, wherein the input signal and the output of the last delay stage are substantially aligned in phase, and wherein each successive delay stage receives the output of a previous stage at both the first input and the second input.

2. The delay line of claim 1, wherein the feedback configures the delay line into a regenerative amplifier, wherein frequency response of the regenerative amplifier has peaking or resonance at frequency of the input signal.

3. The delay line of claim 2, wherein the regenerative amplifier attenuates jitter in the input signal.

4. The delay line of claim 2, wherein relative strength of the feedback to the input signal determines amount of regeneration.

5. The delay line of claim 4, wherein increasing the relative strength of the feedback past a certain level configures the delay line into an injection locked oscillator, where the delay line is used to tune the injection frequency.

6. The delay line of claim 1, wherein each delay stage includes an active delay device.

7-9. (canceled)

10. The delay line of claim 4, wherein each delay stage includes a first device to receive a first signal from the first input and a second device to receive a second signal from the second input, and wherein relative size of the first device to the second device determines relative strength of the first signal to the second signal, and amount of regeneration in the first delay stage.

11. A delay locked loop (DLL) comprising
a phase detector;
a charge pump;
a low pass filter; and
a regenerative delay line having a plurality of delay stages, wherein each delay stage delays the phase of an input clock signal a defined amount, wherein a first delay stage includes a first input to receive the input clock signal and a second input to receive a phase shifted output clock signal of the delay line from a last delay stage as feedback, wherein the input clock signal and the phase shifted output clock signal are substantially aligned in phase.

12. The DLL of claim 11, wherein the feedback clock signal from the output of the regenerative delay line configures the regenerative delay line into a regenerative amplifier, wherein frequency response of the regenerative amplifier has peaking or resonance at frequency of the input clock signal, and wherein the peaking or resonance attenuates jitter in the input clock signal.

13. The DLL of claim 12, wherein relative strength of the feedback clock signal to the input clock signal determines amount of regeneration.

14. The DLL of claim 13, wherein the first delay stage includes a first device to receive the input clock signal from the first input and a second device to receive the feedback clock signal from the second input, and wherein relative size of the first device to the second device determines relative strength of the input clock signal to the feedback clock signal.

15. The DLL of claim 13, wherein increasing relative strength of the feedback clock signal past a certain level configures the regenerative delay line into an injection locked oscillator, wherein the resonant frequency is tuned to frequency of the input clock signal by the DLL.

16. The DLL of claim 11, wherein each successive delay stage after the first delay stage includes a first input and a second input to both receive an output of a previous stage.

17. A delay line to receive a differential clock signal and provide phase shifted versions of the differential clock signal, wherein
the delay line includes a plurality of delay stages coupled in series;
each delay stage is to provide a phase delay of a defined amount;
each delay stage includes a first and a second input associated with a first leg of the differential clock signal, a third and a fourth input associated with a second leg of the differential clock signal, a first output associated with the first leg of the differential signal, and a second output associated with the second leg of the differential clock signal;
a first delay stage is to receive the first leg of the differential clock signal at the first input, a 180 degree phase shifted second leg of the differential clock signal at the second input, the second leg of the differential clock signal at the third input, and a 180 degree phase shifted first leg of the differential clock signal at the fourth input, and is to output a phase shifted first leg of the differential output at the first output and a phase shifted second leg of the differential output at the second output; and
each successive delay stage is to receive the first output of a previous stage at the first and the second inputs and the second output of the previous stage at the third and the fourth inputs, and is to output a further phase shifted first leg of the differential output at the first output and a further phase shifted second leg of the differential output at the second output.

18. The delay line of claim 17, wherein the first delay stage is to act as a regenerative amplifier, wherein frequency response of the regenerative amplifier has peaking or resonance at frequency of the differential clock signal, and wherein the regenerative amplifier attenuates jitter in the differential clock signal.

19. The delay line of claim 18, wherein relative strength of the 180 degree phase shifted second leg of the differential clock signal and the 180 degree phase shifted first leg of the differential clock signal determines amount of regeneration to occur in the regenerative amplifier.

20. The delay line of claim 19, wherein each delay stage includes a first device to receive the first input, a second device to receive the second input, a third device to receive the third input, and a fourth device to receive the fourth input, and wherein relative size of the first and the third devices to the second and the fourth devices determines relative strength of the first and the third inputs to the second and the fourth inputs including the relative strength of the 180 degree phase shifted second leg of the differential clock signal to the first leg of the differential clock signal and the 180 degree phase shifted first leg of the differential clock signal to the second leg of the differential clock signal in the first delay stage.

21. The delay line of claim 17, wherein the first delay stage is to act as an injection locked oscillator, where the delay line is used to tune the injection frequency, if relative strength of the of the 180 degree phase shifted second leg of the differential clock signal and the 180 degree phase shifted first leg of the differential clock signal is increased past a certain level.
